(19) United States
(12) Patent Application Publication
(10) Pub. No.: US 2016/0141157 A1
(43) Pub. Date: May 19, 2016

(54) TARGET FOR THE REACTIVE SPUTTER DEPOSITION OF ELECTRICALLY INSULATING LAYERS

(71) Applicant: OERLIKON SURFACE SOLUTIONS AG, TRÜBBACH, Trübbach (CH)

(72) Inventors: Juerg Hagmann, Sax (CH); Siegfried Krassnitzer, Feldkirch (AT)

(21) Appl. No.: 14/904,343

(22) PCT Filed: Jul. 9, 2014
(86) PCT No.: PCT/EP2014/001884

§ 371 Date: Jan. 11, 2016

Related U.S. Application Data
(60) Provisional application No. 61/843,998, filed on Jul. 9, 2013.

(51) Int. Cl. H01J 37/34; C23C 14/34; C23C 14/00; C23C 14/35

(52) U.S. Cl. CPC H01J 37/3429; C23C 14/35; C23C 14/3485; C23C 14/0036; H01J 2237/3321; H01J 2237/3322

(57) ABSTRACT

A target whose target surface is embodied so that the use of the target for reactive sputter deposition of electrically insulating layers in a coating chamber avoids a production of a spark discharge from the target surface to an anode that is situated in the coating chamber.

### FIELD or THE INVENTION

The present invention relates to a target whose target surface is designed so that the use of the target for reactive sputter-deposition of electrically insulating layers in a coating chamber prevents the production of a spark discharge from the target surface to an anode that is also present in the coating chamber.

### BACKGROUND OF THE INVENTION

Coating processes using sputtering techniques (terms such as “sputtering processes,” “HiPIMS processes,” and “sputter deposition” are used below; all of these processes are to he understood as coating processes that use sputtering techniques) are carried out in vacuum chambers through the use of at least one so-called target, which is connected as a cathode through the application of a negative voltage by means of a voltage supply or power supply. In the sputtering process, at least one additional electrode that is also present in the coating chamber is connected as an anode. A so-called working gas, which as a rule is an inert gas, is introduced into the coating chamber and positively charged ions are generated from it. The positively charged working gas ions are accelerated at the target surface so that impacts with the accelerated ions cause particles to be released from the surface of the target. Depending on process parameters, the particles released from the target are ionized to a certain degree and are deposited onto the substrate surfaces to be coated. If metallic targets are used, then ions generated from the target during the sputtering process are often referred to as metallic ions. Argon is usually, but not absolutely exclusively, used as the working gas.

If non-metallic layers are to be deposited from metallic targets by means of sputtering processes, then a so-called reactive gas can be introduced into the coating chamber, which can react with the metallic ions generated from the metallic target. in this way, the material resulting from the reaction between the reactive gas and the ions generated from the target is deposited as a thin layer onto the substrate surfaces that are to he coated.

Through the use of metallic targets and the introduction of reactive gases such as O₂, N₂, C₂H₂, and CH₄, to name a few, this then results in a reaction on the substrate surface and a formation of corresponding composite materials such as oxides, nitrides, carbides, or a mixture thereof, which mixtures include oxynitrides, carbonitrides, and carboxynitrides.

Due to scattering processes in the ambient gas inside the coating chamber and also due to electrical or electromagnetic attraction forces, the particles already sputtered from the target and ionized atoms are conveyed back to the target. In the context of the present invention, this phenomenon is referred to as “redeposition.” This particularly occurs at the edges of the target because the sputter rate is very low there in comparison to other target surface regions. But redeposition is to be generally expected in large quantities in all regions of the target surface that have a low sputter rate, e.g. outside the racetrack.

The particles, in particular the ionized atoms, that return to the target surface due to so-called “redeposition” can react with reactive gas and thus form a film composed of a composite material resulting from the reaction, which in particular covers the target surface regions with an accelerated “redeposition.”

If the composite material resulting from the reaction is a material with a low electrical conductivity, then an electrically insulating film is formed on the target surface, for example an oxide film, which sooner or later can result in spark discharge problems.

The formation of the insulating coating, e.g. at the target edge, leads to the buildup of a charge between the coating surface and the sputtering target and as a further result, to a disruptive electrical discharge and thus to the production of a spark discharge from the target surface to the anode. The production of spark discharges can destabilize the entire sputtering process and in so doing, can also produce unwanted defects in the layer structure.

In patent specification EP0692138B1, a reactive sputtering process is stabilized in that the polarity of the negative voltage applied to the target is reversed for 1 to 10 microseconds. in this case, the reverse-polarity voltage should be 5 to 20 percent of the negative voltage. This should be able to achieve good stabilization of the discharging in a reactive sputtering process. But this solution is not satisfactory in reactive sputter deposition of some composite materials such as aluminum oxide because such materials have such a high electrically insulating action that when such a film e.g. an aluminum oxide film, is formed on the target surface, the process becomes unstable so that this measure is no longer sufficient to stabilize the process.

In the patent application WO99/63128, a target design is disclosed, which has angled edges that are intended to reduce the tendency of target edges to become covered with coating material. This solution is intended to prevent or at least delay a “redeposition” of particles onto the edge zone of the target. Although the covering of the target edges with coating material can be delayed by means of this measure, any formation of films of very electrically insulating composite materials always involves the danger of spark discharges, particularly from target edges to the anode, which often occurs, for example, in the case of reactive sputter deposition of aluminum oxide layers.

The above-described spark discharge problem is particularly pronounced when depositing aluminum oxide layers by means of a reactive high power impulse sputtering (HiPIMS) process, in which metallic targets made of aluminum and a reactive gas in the form of oxygen are used,

In the sense of the present invention, the term “HiPIMS processes” is used when referring to sputtering processes that use a current density of the sputtering discharge of at least 0.2 A/cm² or greater than 0.2 A/cm², or a power density of at least 100 W/cm or greater than 100 W/cm².

The object of the present invention is to create an embodiment that makes it possible to avoid process instabilities that can arise due to the production of spark discharges between the target and anode during the deposition of electrically insulating layers by means of reactive sputtering processes. The embodiment according to the present invention should also permit electrically insulating aluminum oxide layers to be deposited in a stable process by means of reactive HiPIMS processes using metallic aluminum targets and oxygen as a reactive gas.

### SUMMARY OF THE INVENTION

The object of the present invention is attained in that a target is created for reactive sputter deposition of electrically insulating layers in a coating chamber, characterized in that at least in the surface region, the target includes at least one first region and one second region, where the first region is made of a first material (M₁), which is composed of one or more elements that can react with a reactive gas in such a way that an M₁-containing composite material resulting from the reaction corresponds to the composition of the desired layer material for coating the substrates that are to be coated, and the second region is made of a second material (M₂), which is composed of one or more elements that are inert relative to the above-mentioned reactive gas or can react with the above-mentioned reactive gas in such a way that an M²-containing composite material resulting from the reaction has a higher electrical conductivity in comparison to the M₁-containing composite material, and the second material (M₂) differs from the first material (M₁) in at least one element. The target is used to carry out reactive sputtering processes, in particular reactive HiPIMS processes.

The present invention relates to a target whose target surface is embodied so that the use of the target for reactive sputter deposition of electrically insulating layers in a coating chamber avoids a production of a spark discharge from the target surface to an anode also located in the coating chamber.

### BRIEF DESCRIPTION OF THE DRAWINGS

FIG. 1 shows a target according to the invention,

FIGS. 2a and 2b show the chronological sequence of spark discharges of two different reactive HiPIMS processes.

FIG. 3 is a schematic depiction of a cross-section through a target according to a preferred embodiment of the present invention.

FIG. 4 is a schematic depiction of a cross-section through a target according to another preferred embodiment of the present invention.

FIGS. 5a, 5b, and 5c show three schematic depictions of the cross-sections through three targets, which have been designed according to three other preferred embodiments of the present invention.

FIG. 6 shows the chronological sequence of interfering spark discharges in the example described below.

FIG. 7 shows the measured chromium concentration of the aluminum oxide layers that were deposited on substrates in the example described below.

### DETAILED DESCRIPTION OF THE PREFERRED EMBODIMENTS

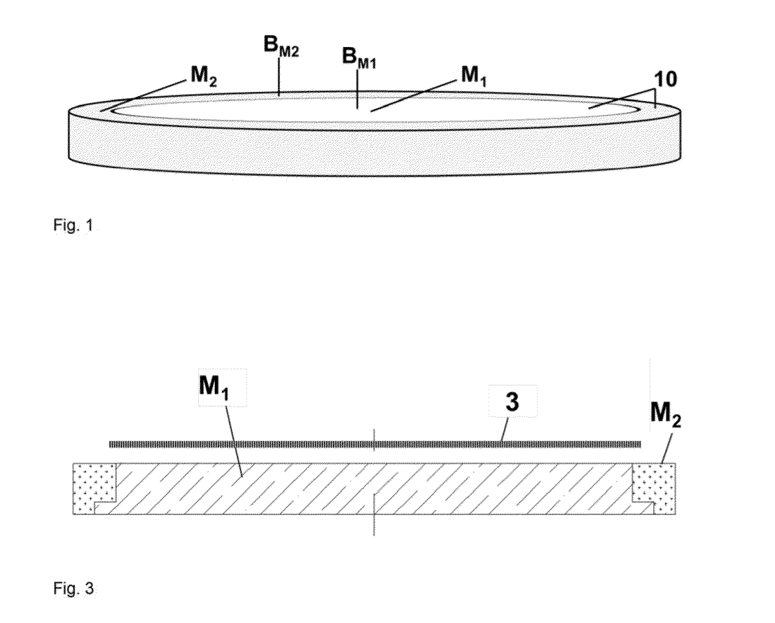

A target according to the present invention is schematically depicted in FIG. 1 and at least in the surface region 10, includes at least one first region B_{M1} and one second region B_{M2}, where
the first region B_{M1} is made of a first material M₁, which is composed of one or more elements that can react with a reactive gas in such a way that the M₁-containing composite material resulting from the reaction corresponds to the composition of the desired layer material for coating the substrates that are to be coated and
the second region B_{M2} is made of a second material M₂, Which is composed of one or more elements that are inert relative to the above-mentioned reactive gas or can react with the above-mentioned reactive gas in such a way that the M₂-containing composite material resulting from the reaction has a higher electrical conductivity in comparison to the M₁-containing composite material, and
M₁≠M₂.

Preferably, the first. region B_{M1} is a region of the target that surrounds the regions of the target surface that are subject to a high erosion rate due to the sputtering of particles from the target. This particularly refers to regions of the target surface where a racetrack is expected. Since the position of a racetrack on the target surface depends on various process parameters, primarily the magnetic field properties in the target, but also for example the target geometry, the first region B_{M1} as defined by the present invention can be selected as a function of the corresponding process parameters and process conditions.

Preferably, the second region B_{M2} is a region of the target that includes regions of the target surface that are subject to a low erosion rate by the sputtering of particles from the target. This particularly refers to regions of the target surface where no racetrack is expected. In a way similar to the selection of the first region B_{M1} the second region B_{M2} as defined by the present invention can be selected as a function of the corresponding process parameters and process conditions.

Preferably, the first region B_{M1} includes the core region of the target, as shown by way of example in FIG. 1.

Preferably, the second region B_{M2} includes the edge region of the target, as shown by way of example in FIG. 1.

Preferably, the second material M₂ is selected so that both M₂ and the M₂-containing composite material resulting from the reaction have an electrical conductivity that is high enough to avoid or preferably completely prevent production of spark discharges between the edge region of the target surface and an anode in the coating chamber.

According to a preferred embodiment of the present invention, the second material M₂ contains at least one element that is also contained in the first material M₁.

According to another preferred embodiment of the present invention, the first material M₁ contains a metal or a combination of metals. For some coating processes, it is advantageous if the first material M₁ is composed of a metal or of a combination of metals.

According to a different preferred embodiment of the present invention, the second material M₂ contains a metal or a combination of metals. For some coating processes, it is advantageous if the second material M₂ is composed of a metal or of a combination of metals.

The present invention is described in greater detail below in conjunction with examples and figures:

Using oxygen as a reactive gas and targets containing aluminum, the inventors have performed a number of coating trials on a high power impulse magnetron sputter coating system of the type Ingenia S3p™ from the company Oerlikon Balzers.

To study the process stability of HiPIMS deposition of oxide layers in an oxygen atmosphere, targets with different chromium contents were tested. This revealed a lower propensity for spark discharging with increasing chromium content. In the inventors' opinion, an explanation for this lies in the reduction of the electrically insulating character of the deposited aluminum chromium oxide layers with an increased chromium content.

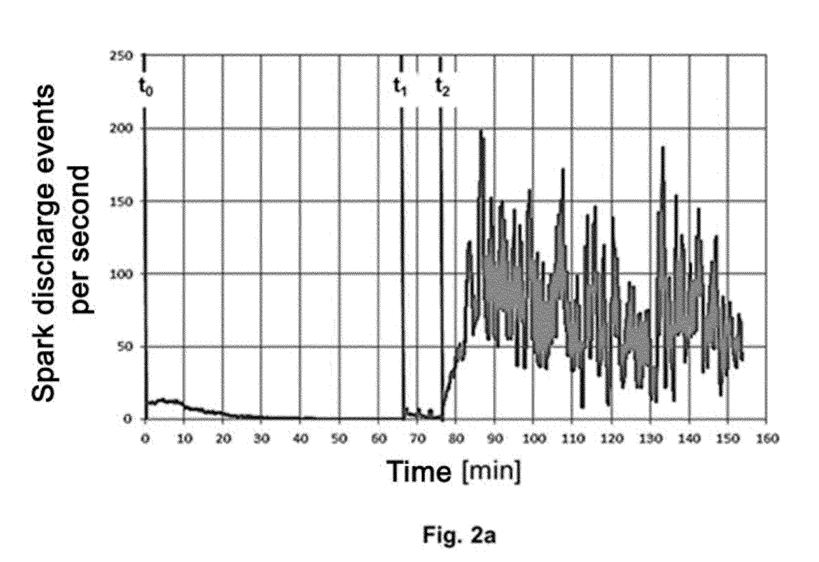

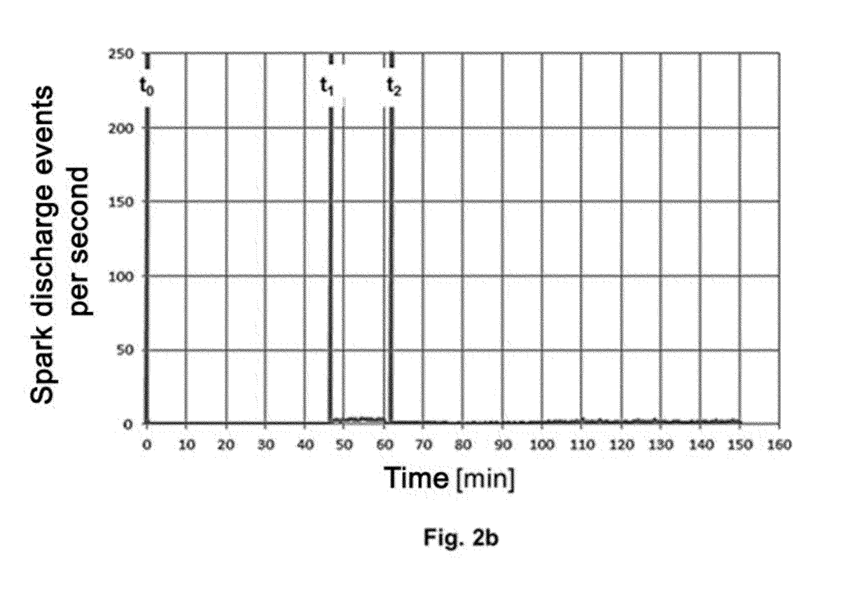

FIG. 2 shows the chronological sequence of spark discharges of two different reactive HiPIMS processes.

The sequence shown in FIG. 2a belongs to a HiPIMS process in which aluminum targets with an aluminum concentration in atomic % of 99.9 at % were used. The sputtering power density used on the target was 300 W/cm². Argon was first introduced into the coating chamber and used as working gas. The process was carried out in a pressure-controlled fashion, with an overall process pressure of 0.6 Pa. To condition the target, the sputtering process on the target was started at a time t₀ behind a shutter in the argon atmosphere. After the target conditioning interval, at a time t₁, oxygen was introduced into the coating chamber and the oxygen partial pressure was kept at 100 mPa. At a time t₂, the shutter was removed from the target so that from this time forward, the deposition of the oxide layer onto the substrate surfaces to be coated could begin. As shown in FIG. 2a, intense and frequent spark discharges were observed during the deposition of the oxide layer. After performing the HiPIMS process, the inventors inspected the targets used and ascertained clear traces of spark discharges on the edge region of the target surface.

The sequence shown in FIG. 2b belongs to a HiPIMS process in which aluminum chromium targets with an aluminum chromium concentration in atomic % of 50:50 at % were used. Otherwise, the same process parameters and the same process sequence as in the above-described HiPIMS process were used. As shown in FIG. 2b, this time, no clear spark discharges during the deposition of the oxide layer could be ascertained. The inventors likewise tested the targets used after performing the HiPIMS process, but this time, no traces of spark discharges in the edge region of the target surface could be ascertained.

After these tests, the inventors then suddenly had the idea to design a target, which, in addition to a material M₁ for the deposition of the desired layer, has a second material M₂ at least in the edge region of the target surface, which does not tend to produce spark discharges during a reactive sputtering or HiPIMS layer deposition.

In the following, a plurality of preferred embodiments of targets with embodiments according to the present invention are disclosed, which achieve a reduced propensity for disruptive electrical discharge or a reduced propensity for producing spark discharges, and consequently a deposition of electrically insulating layers in a stable process by means of reactive sputtering or HiPIMS processes.

FIG. 3 is a schematic depiction of a cross-section through a target according to a preferred embodiment of the present invention. The first material M₁ , which is used in order to produce the desired layer, is situated in the core region of the target. The second material M₂, which has a lower propensity than M₁ to produce spark discharge during reactive sputtering processes, is situated in composition with the first material M1 in the edge zone of the target where a greater erosion takes place. As mentioned above, a greater propensity to produce spark discharge is particularly expected in the regions of the target surface in which a slight erosion takes place during the sputtering process and in which no racetrack is found. This is why the second material M₂ should be positioned in precisely this location. Since the regions of the target where the second material M₂ should be present according to the present invention are characterized by means of a low sputter rate, the percentage of this material M₂ should be very low in the composition of the layers deposited onto the substrates to be coated. The dimensions of the area of the target region that is referred to here as the core region of the target can, as shown in FIG. 3, vary over the thickness of the target. FIG. 3 also shows a plasma region 3 that is formed by the magnetic fields of the magnetron and overlaps the materials M₁ and M₂ at least at the edge region of the target.

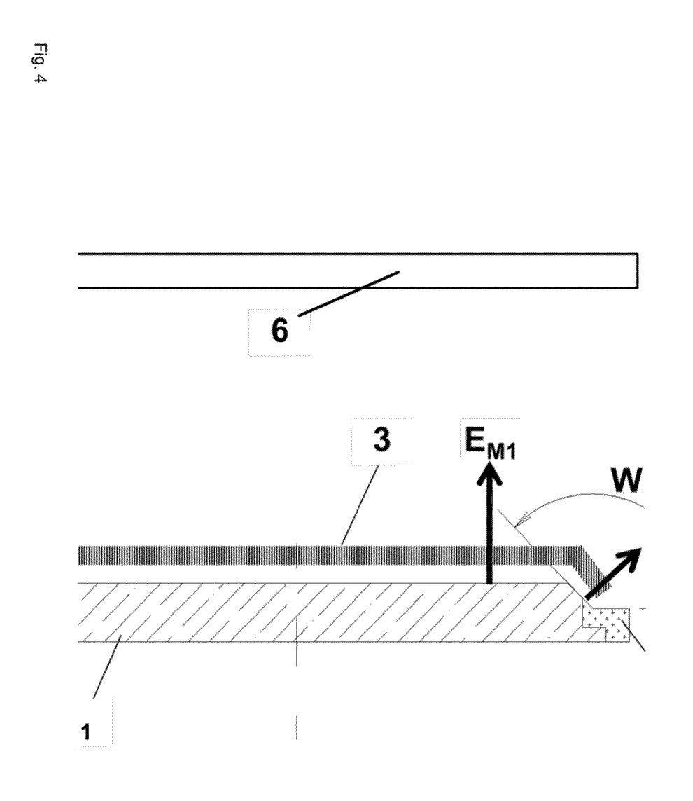

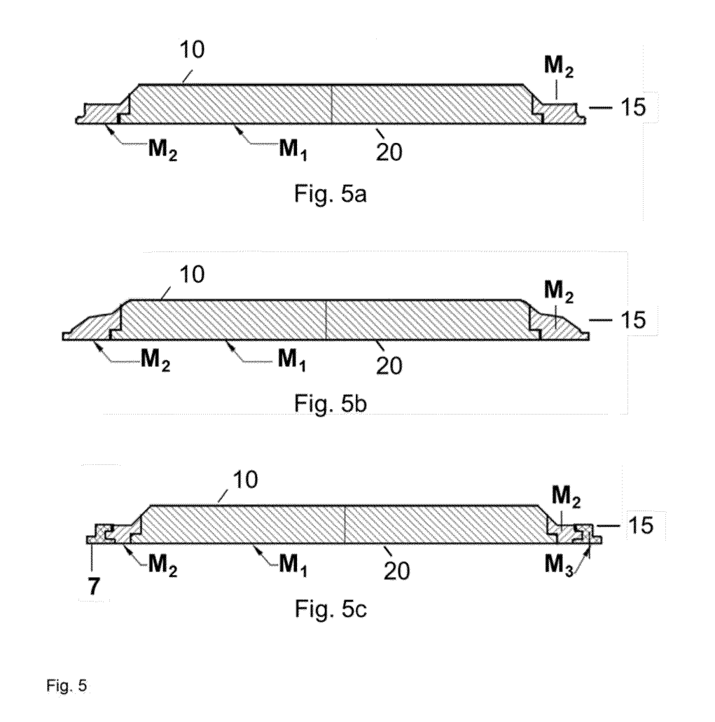

In some tests, it was ascertained that it can be advantageous if the dimensions of the target core region composed of material M₁ in the front region or surface region 10 of the target are smaller than in the back region 20 of the target, as schematically depicted, for example, in FIGS. 3 and 5.

FIG. 4 is a schematic depiction of a cross-section through a target according to another preferred embodiment of the present invention, in order to prevent the concentration of the second material M₂ from becoming so high that it negatively affects the layer properties of the layers deposited using this method, the target is embodied so that it has a set angle W in the “mixing region” of the target in which both the first and second material are present. The set angle W is used to selectively mask the second material M₂, which is undesirable for the layer structure. The arrows E_{M1} and E_{M2} in FIG. 4 indicate the preferred emission directions of the first material M₁ and second material M₂, which are to be expected due to the use of a target according to this embodiment of the present invention. FIG. 4 also shows an example of a substrate 6 that is to be coated.

FIG. 5 shows three schematic depictions of the cross-sections through three targets, which have been designed according to three other preferred embodiments of the present invention.

FIG. 5a shows one variation of the embodiment already shown in FIG. 4. According to this variation, the target contains at least one recess in the lateral edge region 15 in order to make the target easier to mount in the coating system. According to this embodiment, the interface between the materials M₁ and M₂ is preferably contained in the bevel.

FIG. 5b shows one embodiment in which the target is embodied so that it has two bevels. In this case, an even lesser degree of redeposition or a less pronounced growth of a film on the target surface—resulting from the reaction of the target material with the reactive gas—is achieved in region B_{M1}. It is also preferable, as shown in FIG. 5b, for the edgy regions, which can be present at the beginning and/or end of each bevel, to be rounded after the corresponding production in order to avoid possible geometrically induced spark discharges or short circuits.

The embodiment shown in FIG. 5c has a target according to the invention, in which a bayonet mount 7, e.g. a bayonet ring, is used to hold the target during the sputtering process; the bayonet holder 7 is composed of a third material M₃, which preferably has a good mechanical stability even at high temperatures.

Since the production of aluminum oxide layers (Al₂O₃) has an especially high need for process stability, the inventors deposited aluminum oxide layers using HiPIMS processes and using targets embodied according to the invention in order to ascertain the improvement in process stability.

The results of one of the trials performed according to the invention are reported below as an example:

The aluminum oxide layers were produced by means of a reactive HiPIMS process, which was performed with the following process parameters:
working gas: argon
reactive gas: oxygen
process pressure: 0.6 Pa
oxygen partial pressure: 100 mPa
power density: 300 W/cm²
target having the embodiment of the present invention shown in FIG. 5a, with M₁=aluminum in a concentration of 99.9 at % (Al 99.9 in at %) and M aluminum and chromium, each in a concentration of 50 at % (AlCr 50:50 in at %)

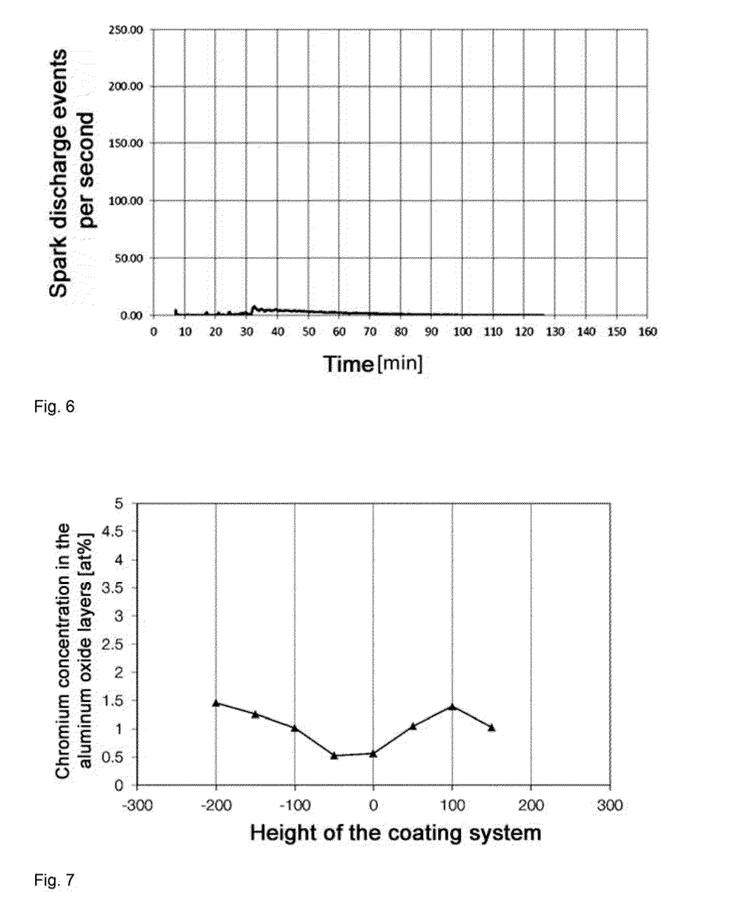

The chronological sequence of interfering spark discharges in this process is shown in FIG. 6. No relevant spark discharges were detected during the reactive HiPIMS deposition of the electrically insulating aluminum oxide layers according to the invention. The covering region (i.e. the regions of the target that experience increased coverage with the film resulting from the reaction of the target material and the reactive gas) did not show any traces of spark discharge. The “mixture region” (also referred to above as the “mixing region”), in which the first material Al and the second material AlCr are situated next to each other, permitted uniform sputtering to be achieved. This was evident from the fact that only a very small amount of aluminum oxide covering of the target surface was detected in the “mixture region.” The region referred to here as the “mixture region” includes the surface regions next to the interface region between M₁ and M₂ and particularly in this case, the entire surface region of the bevel that is present on the target surface. The term “aluminum oxide covering” here refers to the electrically insulating aluminum oxide film that results from the reaction between the reactive gas (oxygen in this case) and the first material M₁ (aluminum in this case). Aluminum chromium oxide covering of the target surface could be detected in the edge region of the target surface, but because of the higher electrical conductivity in comparison to aluminum oxide, this covering did not result in any process instabilities due to interfering spark discharges.

The chromium concentration in the deposited aluminum oxide layers was less than 1.5 at %, as shown in FIG. 7. Consequently, the layer properties of the aluminum oxide layers were not negatively affected. FIG. 7 shows the measured chromium concentration of the aluminum oxide layers that were deposited on substrates, which were distributed to various positions throughout the height of the coating chamber. The point 0 on the horizontal axis in this example is understood to be the plane in the vertical direction of the coating system (in other words: the height in the coating system) at which the center of the target is located.

1. A target for reactive sputter deposition of electrically insulating layers in a coating chamber, the target comprising at least in a surface region:
at least one first region (B_{M1}) is made of a first material (M₁), which is composed of one or more elements that can react with a reactive gas in such a way that an M₁-containing composite material resulting from the reaction corresponds to the composition of the desired layer material for coating substrates that are to be coated; and
at least one second region (B_{M2}) made of a second material (M₂), which is composed of one or more elements that are Men relative to the above-mentioned reactive gas or can react with the above-mentioned reactive ₕas in such a way that an M₂-containing composite material resulting from the reaction has a higher electrical conductivity in comparison to the M₁-containing composite material,
wherein the second material (M₂) differs from the first material (M₁) in at least one element.

2. The target according to claim 1, wherein the target surface has at least one bevel, which is defined by a set angle (W) and in the beveled target surface region, there is a “mixing region” in which the first material (M₁) and the second material (M₂) are situated next to each other.

3. The target according to claim 1, wherein the first region (B_{M1}) includes the a core region of the target.

4. The target according to claim 1, wherein the second region (B_{M2}) includes an edge region of the target.

5. A method for coating substrates with at least one layer comprising depositing the at least one layer using at least one target according to claim 1.

6. The method according to claim 5, comprising depositing the layer at least partially by using a reactive sputtering process and/or at least partially by of using a reactive HiPIMS process and using reactive gas in the process in order to produce the layer as a result of a reaction between the sputtered target material and the reactive gas.

7. The method according to claim 6, wherein an erosion rate in the surface region of the target during the sputtering process and/or HiPIMS process is greater in the first region of the target (B_{M1}) than in the second region of the target (B_{M2}).

8. The method according to claim 7, wherein the layer is electrically insulating.

9. The method according to claim 8, wherein the erosion rate in the surface region of the target during the sputtering process and/or HiPIMS process is greater in the first region of the target (B_{M1}) than in the second region of the target (B_{M2}).

10. The method according to claim 6, wherein at least most of the layer has a composition that corresponds to the composition of a composite material resulting from the reaction between the first target material (M₁) and the reactive gas.

11. The method according to claim 6, wherein the reactive gas is oxygen or nitrogen or a mixture thereof.

12. The method according to claim 6, wherein the first target material (M₁) contains at east mostly aluminum.

13. The method according to claim 6, wherein the second target material (M₂) contains aluminum and chromium.

14. The method according to claim 13, wherein the first material (M₁) contains aluminum in a concentration of at least 99.9% in atomic % and the layer contains at least mostly aluminum oxide.

15. The method according to claim 14, wherein the second material (M₂) contains aluminum and chromium in a concentration of 50:50% in atomic %.
